(19) United States
(12) Patent Application Publication
(10) Pub. No.: US 2002/0126851 A1
(43) Pub. Date: Sep. 12, 2002

(54) Multiple use sounding device

(76) Inventors: Yuen Wing Lo, Kowloon (HK); Chi Hing Kwong, Kowloon (HK)

Correspondence Address: Adams, Schwartz & Evans, P.A., 2180 Two First Union Center, Charlotte, NC, 28282, US

(21) Appl. No.: 09/956,333

(22) Filed: Sep. 18, 2001

Related U.S. Application Data
(60) Provisional application No. 60/233,701, filed on Sep. 19, 2000.

(51) Int. Cl. H03G 3/00; B65D 23/00

(52) U.S. Cl. 381/61; 381/124; 215/400

(57) ABSTRACT

A sounding device includes an assembly housing. A sensor including a clock signal defines a base level capacitance. A circuit medium is located within the assembly housing and includes a control circuit and an output circuit. The control circuit is operatively connected to the sensor, and adapted for generating a signal output in response to a threshold change in the base level capacitance. A loudspeaker is operatively connected to the output circuit, and is activated by the signal output for producing outwardly radiating acoustical energy in a frequency range sufficient to be heard by a user.

This patent application claims priority to U.S. Provisional Patent Application No. 60/233,701 filed on Sep. 19, 2000.

### TECHNICAL FIELD AND BACKGROUND OF INVENTION

This invention relates to a multiple use sounding device. The invention is especially applicable for use and enjoyment by infants and children. Although resembling conventional products, such as infant “sippy” cups and cereal bowls, the invention produces a novel entertaining sound in response to a triggering event. In one instance, sound is produced when a beverage is consumed by the user. In another instance, the trigger event is simply the act of holding or touching the product with the hand. The sound may include a short melody, a funny voice or message, or other entertaining noise intended to amuse the user.

In other applications, the invention is incorporated into home safety products, such as a door knot cover, stove knot lock, security gate, and stove top shield. When the product is touched, an alarm sound or message is produced alerting parents to attend to their child. In another application, the invention is a safety door chime completely sealed by plastic. Since the invention has no contact switches, no electrical sparks form when the user touches and rings the door bell. In yet another application, the invention is a low cost home security alarm system.

### SUMMARY OF THE INVENTION

It is an object of the invention to provide a multiple use sounding device in the form of a learning cup which produces an entertaining noise when an infant or child consumes a consumable substance contained in the cup.

It is another object of the invention to provide a multiple use sounding device which utilizes a touchless and switchless circuit to activate a loud speaker stored in the device.

It is another object of the invention to provide a multiple use sounding device which utilizes a capacitance coupling to transfer energy from one electronic circuit to another.

It is another object of the invention to provide a multiple use sounding device which employs a capacitance relay for triggering a signal output to activate a loudspeaker stored in the device.

It is another object of the invention to provide a multiple use sounding device which employs a RC oscillator base capacitance level change detector.

These and other objects of the present invention are achieved in the preferred embodiments disclosed below by providing a sounding device including an assembly housing. A sensor including a clock signal defines a base level capacitance. A circuit medium is located within the assembly housing and includes a control circuit and an output circuit. The control circuit is operatively connected to the sensor, and adapted for generating a signal output in response to a threshold change in the base level capacitance. A loudspeaker is operatively connected to the output circuit, and is activated by the signal output for producing outwardly radiating acoustical energy in a frequency range sufficient to be heard by a user.

According to another preferred embodiment of the invention, a battery cooperates with the signal output to operate the loudspeaker.

According to another preferred embodiment of the invention, the assembly housing is formed of plastic.

According to another preferred embodiment of the invention, a radio magnetic frequency shield is embedded in the assembly housing to protect the sensor from external interference.

According to another preferred embodiment of the invention, the device is an infant learning cup.

According to another preferred embodiment of the invention, a drinking straw is adapted for use in consuming a beverage contained in the learning cup.

According to another preferred embodiment of the invention, the learning cup has one or more handles.

According to another preferred embodiment of the invention, the device is a sounding bowl.

According to another preferred embodiment of the invention, the device is a security gate.

According to another preferred embodiment of the invention, the device is a door knot cover.

According to another preferred embodiment of the invention, the device is a stove knot lock.

According to another preferred embodiment of the invention, the device is a stove top shield.

According to another preferred embodiment of the invention, the device is a badge.

According to another preferred embodiment of the invention, the device is a door chime.

According to another preferred embodiment of the invention, the device is a security system.

According to another preferred embodiment of the invention, the device is a cap for drinking vessel.

According to another preferred embodiment of the invention, the device is a table mat.

### BRIEF DESCRIPTION OF THE DRAWINGS

Some of the objects of the invention have been set forth above. Other objects and advantages of the invention will appear as the description proceeds when taken in conjunction with following drawings, wherein:

FIGS. 1 and 2 are views of sounding device in the form of an infant learning cup according to one preferred embodiment of the invention;

FIG. 3 is a schematic illustrating the electronics of the circuit board;

FIG. 4 is a diagram of the control circuit;

FIG. 5 is a block diagram of the control circuit;

FIG. 6 is a chart of signal illustrating operation of the sounding cup;

FIGS. 7 and 8 are views of the device in the form of a sounding cup with a built-in drinking straw;

FIGS. 9, 10, and 11 are views of a sounding cup with a removable drinking straw according to a further embodiment of the invention;

FIGS. 12, 13, and 14 are views of the device in the form of an infant sounding cup;

FIG. 15, 16, and 17 are views of the device in the form a sounding bowl;

FIGS. 18 and 19 are views of the device in the form of a security gate for infants and children;

FIGS. 20, 21, and 22 are views of the device in the form of a sounding door knot cover;

FIGS. 23, 24, and 25 are views of the device in the form of a sounding stove knot lock;

FIGS. 26 and 27 are views of the device in the form of a sounding stove top shield;

FIGS. 28 and 29 are views of the device in the form of a sounding badge;

FIGS. 30 and 31 are views of the device in the form of a light-up badge;

FIGS. 32 and 33 are views of the device in the form of a safety door chime;

FIGS. 34 and 35 are views of the device in the form of a home security system;

FIGS. 36 and 37 are views of the device in the form of sounding cap for drinking cups; and

FIGS. 38 and 39 are views of the device in the form of a sounding table mat.

### DESCRIPTION OF THE PREFERRED EMBODIMENT AND BEST MODE

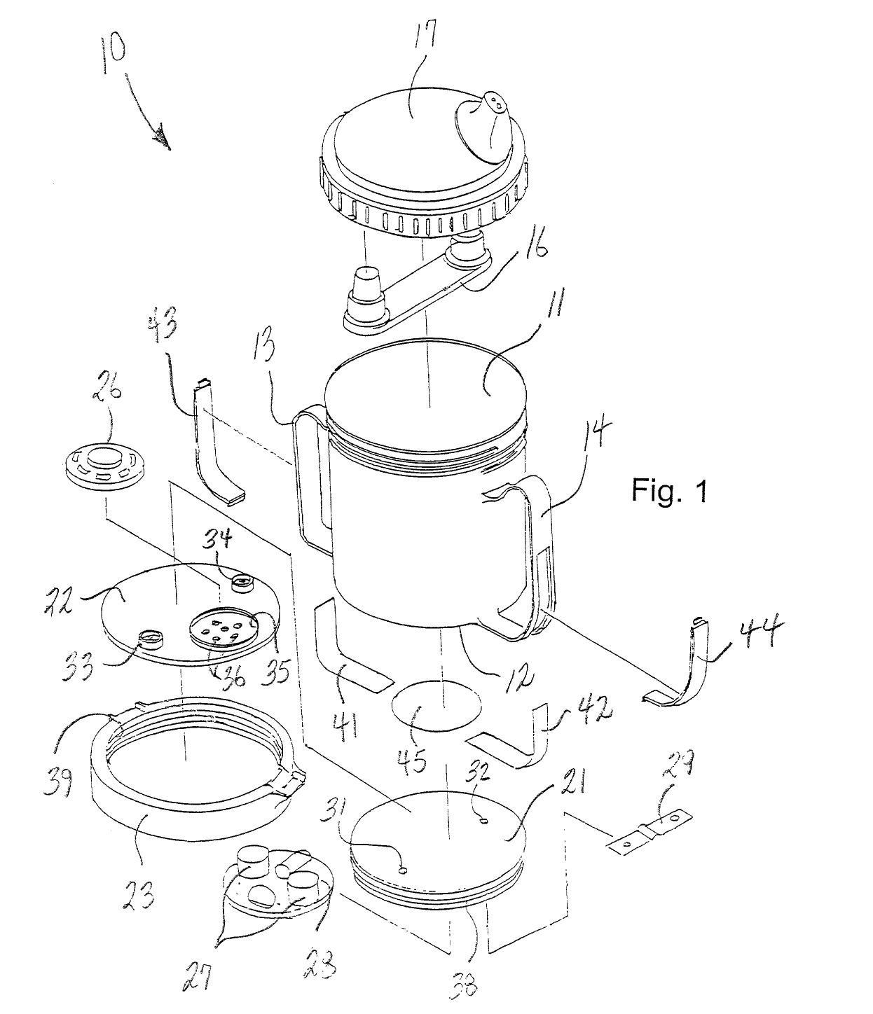

Referring now specifically to the drawings, a multiple use sounding device according to the present invention is illustrated in FIG. 1. In this embodiment, the sounding device comprises an infant learning cup shown generally at reference numeral 10. The learning cup 10 includes a cylindrical cup body 11 having a closed bottom 12 forming a drinking vessel, a pair of cup handles 13 and 14, and a removable base assembly 15. A standard conceal ring 16 and infant mouth piece cover 17 are located at the open top of the cup 10.

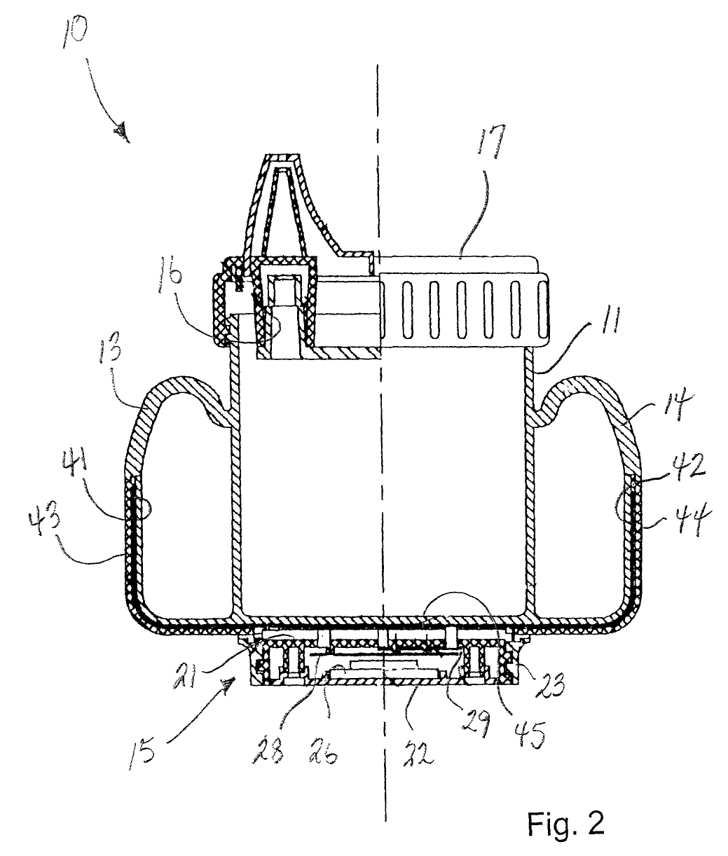

As shown in FIGS. 1 and 2, the base assembly 15 includes upper and lower base sections 21 and 22 held together by a tousing ring 23, and cooperating to define an open space for storing a loudspeaker 26, batteries 27, circuit board 28, and metal contact plate 29. A pair of spacers 31 and 32 depend from the upper base section 21, and extend within locating rings 33 and 34 formed with the lower base section 22 to space and locate the lower base section 22 relative to the upper base section 21. An annular recess 35 is formed in the lower base section 22 for locating the loudspeaker 26, and includes a number of acoustic ports 36. Preferably, complementary screw threads 38 and 39 are formed with the upper base section 21 and tousing ring 23 to join the base assembly 15 together. Metal handle sensors 41 and 42 are positioned within the handles 13 and 14 of the cup 10, and are covered by removable handle caps 43 and 44. A third metal sensor 45 is located adjacent the closed bottom 12 of the cup 10. The sensors 41, 42, and 45 are operatively connected to the circuit board 28 via the contact plate 29 and function to detect changes in capacitance, as described below.

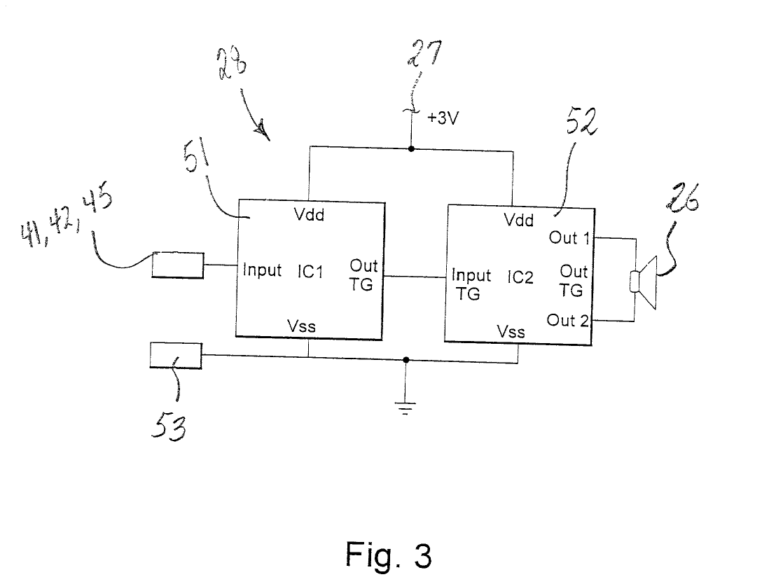

Referring to FIG. 3, 4, and 5, the circuit board 28 includes a control circuit 51 communicating with the sensors 41, 42, and 45 contained in the handles 13, 14 and closed bottom 12, and a sound output circuit 52 operatively connected to the control circuit 51, batteries 27, and loudspeaker 26. The base sensor 45 and liquid contained in the learning cup 10 form respective electrodes insulated from each other by a dielectric created by the closed bottom 12. The resulting assembly forms a capacitor which is used to couple capacitance changing inside the learning cup 10. A radio magnetic frequency shield 53 is embedded in the tousing ring 23 to prevent external signal interference.

A self generated clock signal or other suitable capacitance measuring device is used to generate a base level capacitance inside the learning cup 10. The capacitance level changes as a result of liquid disturbance caused by, for example, drinking or stirring the liquid beverage. The handle sensors detect capacitance level changes caused by holding the handles. The capacitance change is indicated by means of a phase shift or amplitude change in the clock signal. In one application, a twenty to fifty percent change in amplitude represents a threshold capacitance change. Thus, if the battery power supply is 3V and the clock frequency is 26 Khz with a base signal level of 1.7V per phase, then a threshold capacitance change would occur at 1.3V per phase.

Upon occurrence of a capacitance change in the sounding cup 10, the new level of capacitance is coupled to the contact plate 29 and fed to the control circuit 51. The capacitance is then amplified and compared to the base level capacitance. If the capacitance change is sufficient to meet or exceed the predetermined threshold, then a signal output is transmitted from the control circuit 51 to the sound output circuit 52. The sound output circuit 52 cooperates with the battery charge to activate the loudspeaker 26 which produces an entertaining, audible sound to the user.

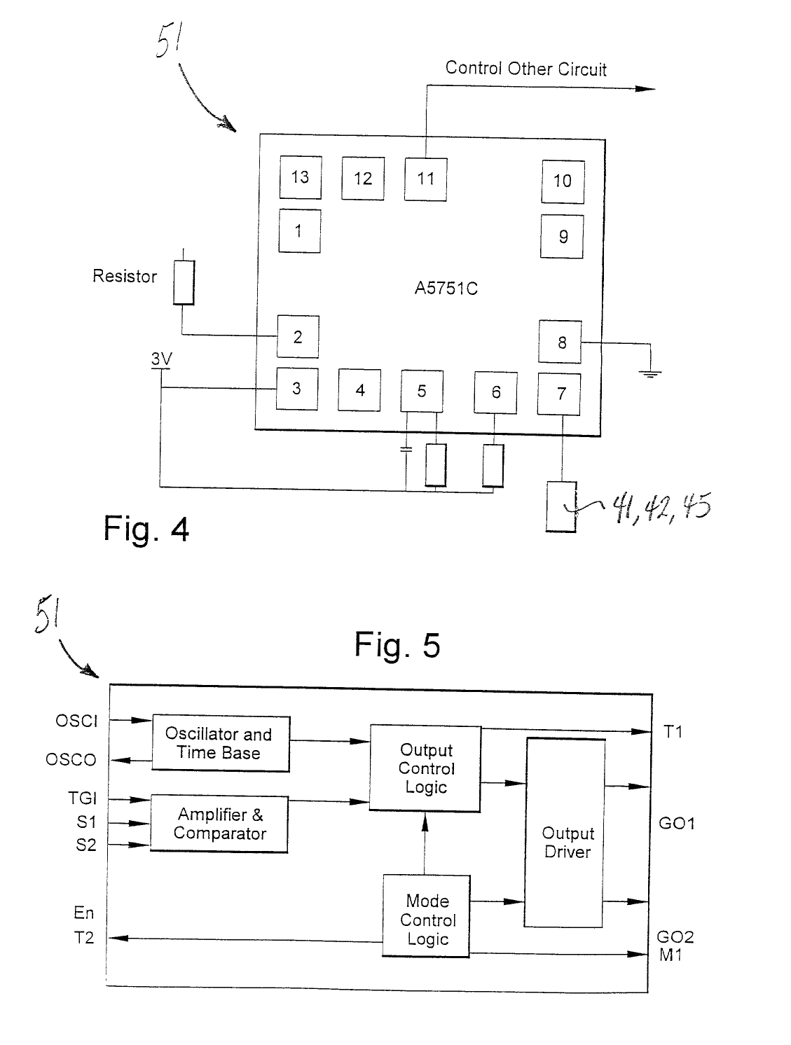

The pad description for the diagrams of FIGS. 4 and 5 is provided below.

| Number | Name | Description |
|---|---|---|
| 1 | OSCI | Oscillator Input |
| 2 | OSCO | Oscillator Output |
| 3 | VDD | Power Supply |
| 4 | T1 | Test Pin 1 |
| 5 | S1 | Sensitivity Adjust 1 |
| 6 | S2 | Sensitivity Adjust 2 |
| 7 | TG1 | Capacitance Sensor |
| 8 | VSS | Ground |
| 9 | En | Chip Enable |
| 10 | T2 | Test Pin 2 |
| 11 | GO1 | Positive Pulse Output |
| 12 | GO2 | Negative Pulse Output |
| 13 | M1 | Mode Indicator |

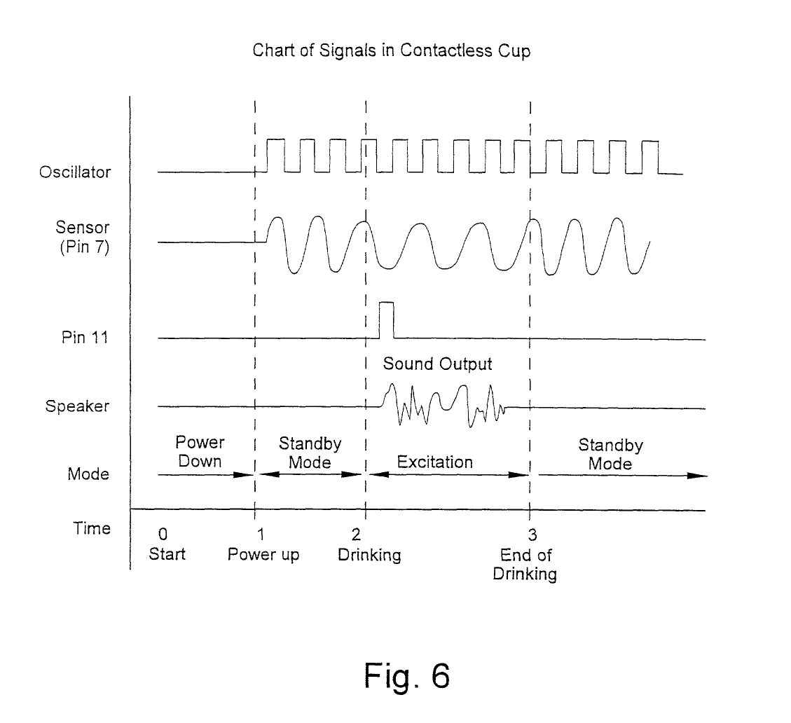

A chart of signals illustrating operation of the learning cup 10 is provided in FIG. 6. From a power down mode, upon grasping the sounding cup with the hand, the control circuit moves into standby mode. When the beverage consumed by the user, the control circuit signals the sound output circuit to activate the loudspeaker creating the entertaining sound output. After drinking, the control circuit moves back into standby mode and then into the power down mode.

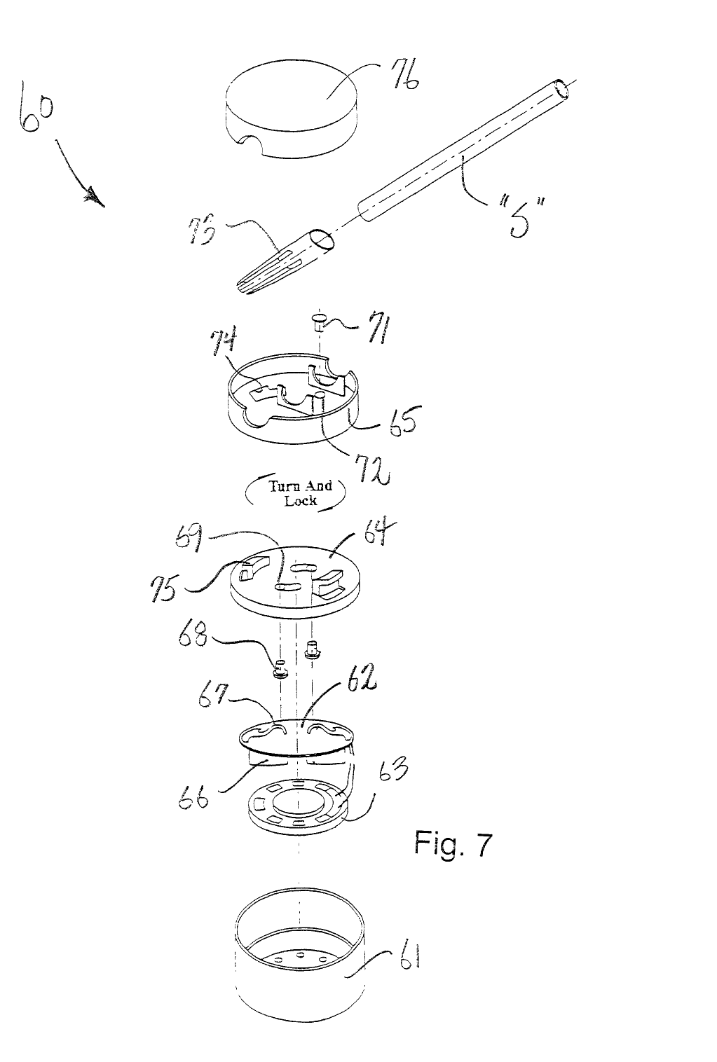

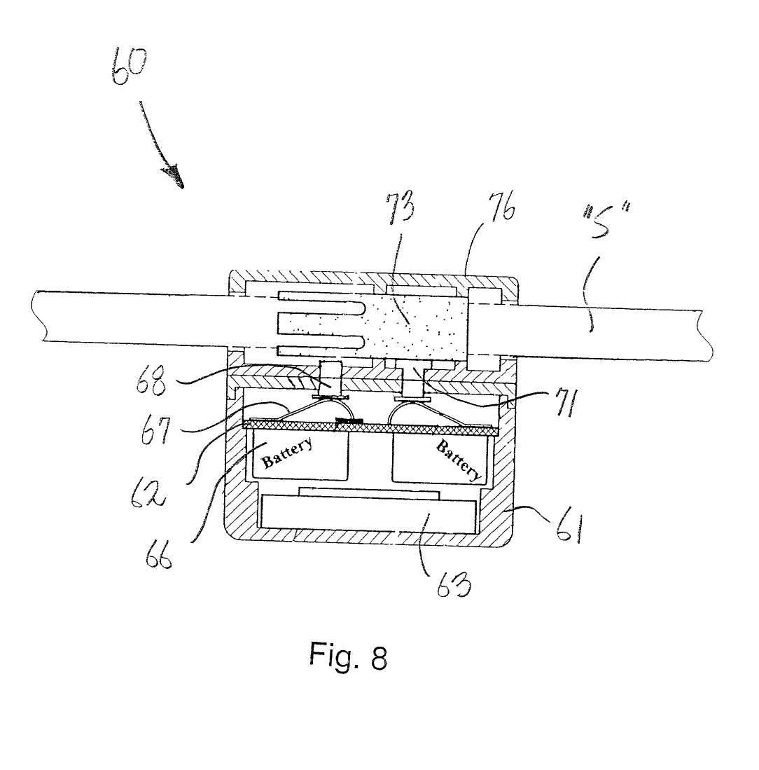

A sounding unit 60 with a built-in drinking straw “S” is illustrated in FIGS. 7 and 8. The sounding unit 60 includes an assembly housing 61 for storing a circuit board 62, a loudspeaker 63 electrically connected to the circuit board 62, a mounting disc 64, and straw holder 65. The circuit board 62 contains a control circuit and sound output circuit, such as previously described. Batteries 66 and metal spring contacts 67 are carried by the circuit board 62. The spring contacts 67 engage respective metal contacts 68 extending through openings 69 in the mounting disc 64. Contact 71 engages contact 68 through an opening 72 in the straw holder 65, and contacts a metal sensor 73 attached to the drinking straw “S”. The straw holder 65 and mounting disc 64 are removably attached together by cooperating openings 74 (only one shown) formed in the straw holder 65 and projecting shoulders 75 formed with the mounting disc 64. Once assembled, a plastic top cover 76 is applied to the assembly housing 61 over the drinking straw “S”.

When a beverage is consumed through the drinking straw “S”, the metal sensor 73 detects a capacitance change in the sounding unit 60, as previously described. The new level of capacitance is fed to the control circuit through the metal contacts 68 and 71 and spring contacts 67. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 63 which produces an entertaining, audible sound to the user.

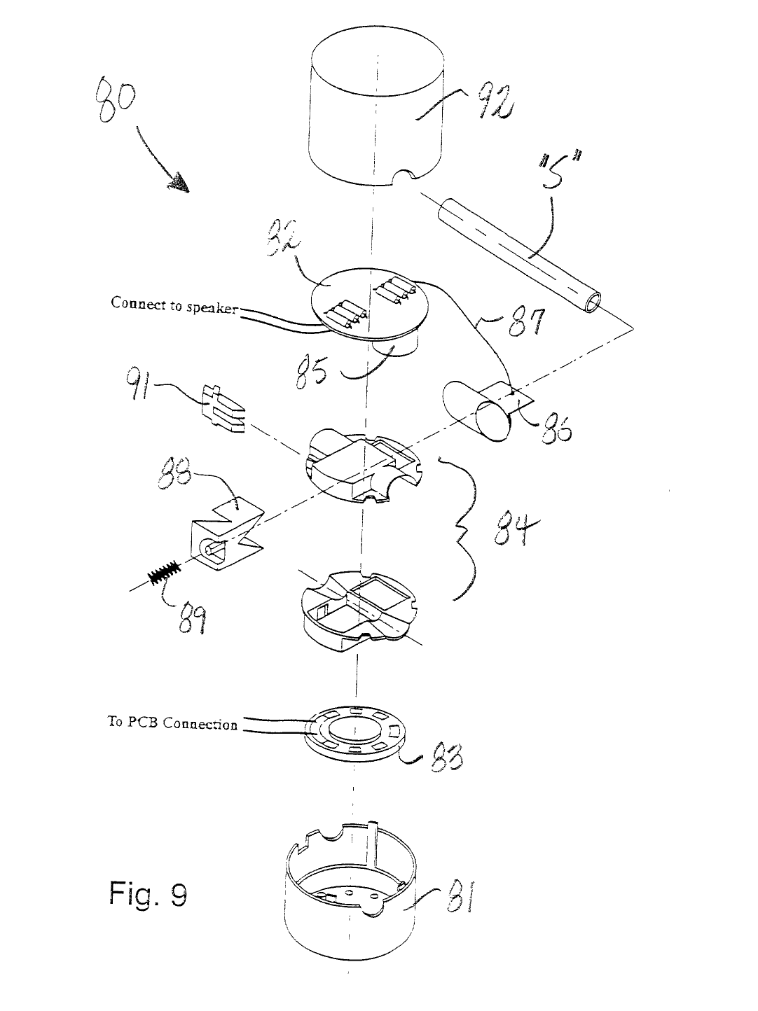

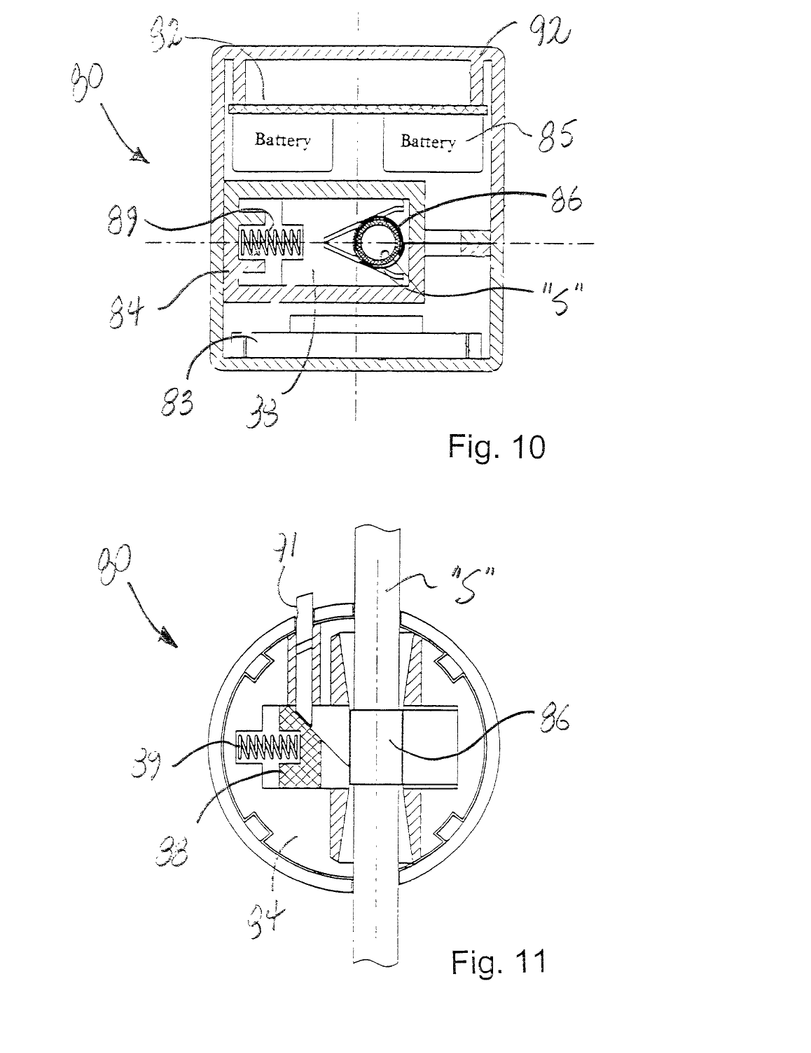

A further embodiment of the sounding unit 80 is shown in FIGS. 9, 10, and 11. The sounding unit 80 includes a removable drinking straw “S” and an assembly housing 81 for storing a circuit board 82, a loudspeaker 83 electrically connected through wires to the circuit board 82, and a control housing 84. The circuit board 82 contains a control circuit and sound output circuit, as previously described. Batteries 85 are carried by the circuit board 82 to activate the loudspeaker 83. The drinking straw “S” extends through a metal sensor 86 located within the control housing 84 and electrically connected through wire 87 to the circuit board 82. The control housing 84 contains a sliding piece 88 and spring 89, and a push button 91 for actuating the sliding piece 88. Once assembled, a plastic top cover 92 is applied to the assembly housing 81 over the drinking straw “S”.

When a beverage is consumed through the drinking straw “S”, the metal sensor 86 detects a capacitance change in the sounding unit 80, as previously described. The new level of capacitance is fed to the control circuit through wire 87. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 83 which produces an entertaining, audible sound to the user.

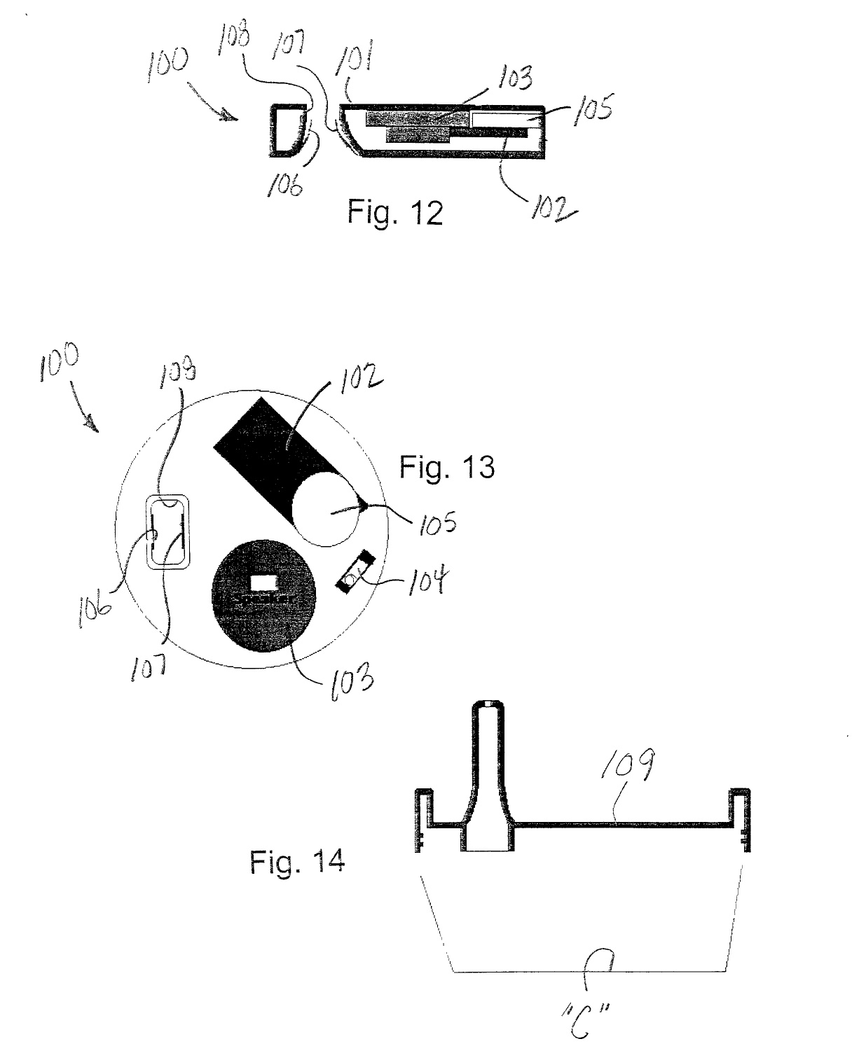

FIGS. 12, 13, and 14 illustrate a sounding cap 100 adapted for use in an infant learning cup “C”. The cap 100 includes top and bottom covers defining an assembly housing 101 containing a circuit board 102, a loudspeaker 103 electrically connected to the circuit board 102, and an on/off switch 104. The circuit board 102 contains a control circuit and sound output circuit, as previously described. A battery 105 is carried by the circuit board 102 to activate the loudspeaker 103. A metal sensor 106 and radio magnetic frequency shield 107 are located at the entrance of the drinking tunnel 108. The assembly housing 101 is snap-fit inside the outer structure 109 of the sounding cap 100, and the cap 100 applied to the learning cup “C”.

When a beverage is consumed at the outer structure 109 through the drinking tunnel 108, the metal sensor 106 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 103 which produces an entertaining, audible sound to the user.

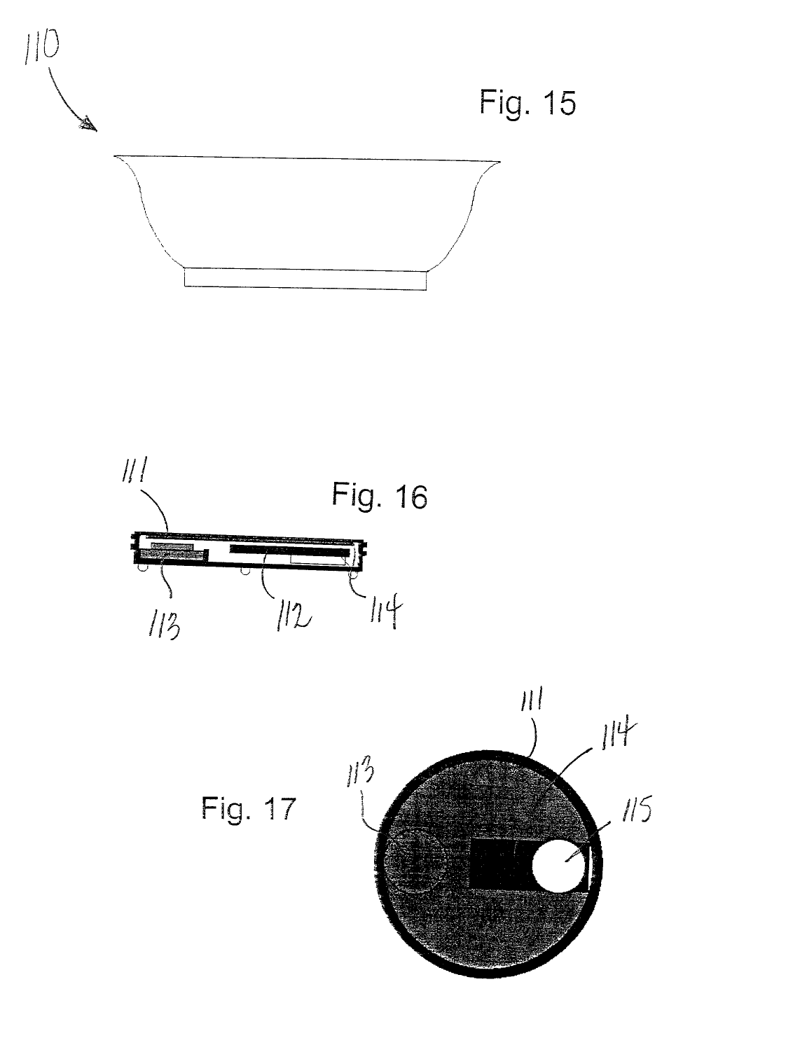

FIGS. 15, 16, and 17 illustrate a sounding bowl 110. The bowl 110 includes abase housing 111 containing a circuit board 112, a loudspeaker 113 electrically connected to the circuit board 112, and a metal sensor 114. The circuit board 112 contains a control circuit and sound output circuit, as previously described. A battery 115 is carried by the circuit board 112 to activate the loudspeaker 113. The base housing 111 has an external thread 116 which mates within a complementary thread inside the base of the sounding bowl 110 to removably attach the base housing 111 to the bowl 110.

Using a metal spoon, when a user consumes a food product contained in the bowl 110, the metal sensor 114 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 113 which produces an entertaining, audible sound to the user.

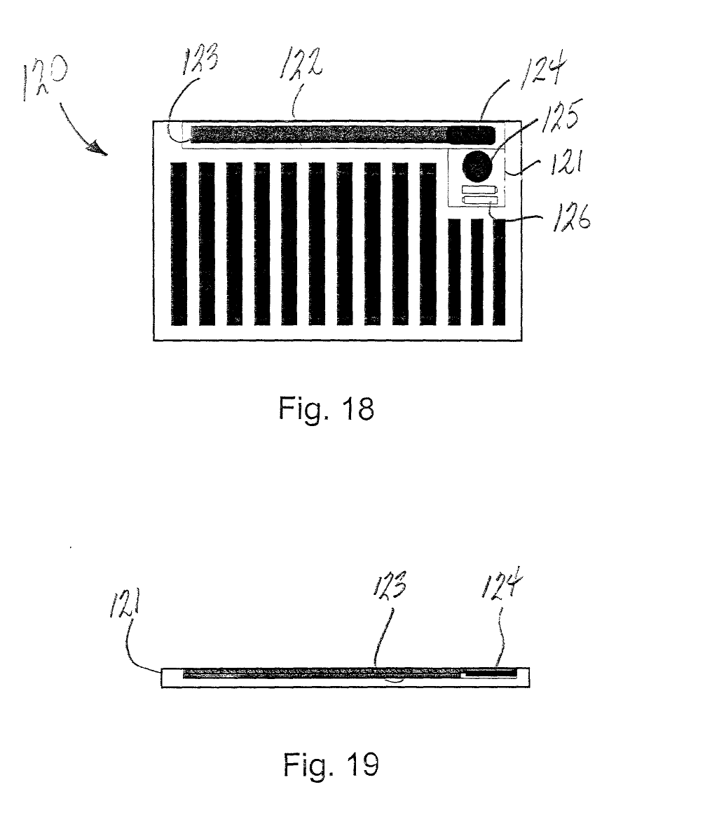

FIGS. 18 and 19 illustrate a sounding security gate 120 for infants. The security gate 120 includes an assembly housing 121 and top rail 122. The top rail 122 contains a metal sensor 123 communicating with the assembly housing 121. The assembly housing 121 contains a circuit board 124, and a loudspeaker 125 electrically connected to the circuit board 124. The circuit board 124 includes a control circuit and sound output circuit, as previously described. Batteries 126 are carried by the circuit board 124 to activate the loudspeaker 125.

When an infant touches the top rail 122, the metal sensor 123 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 125 which produces an audible warning.

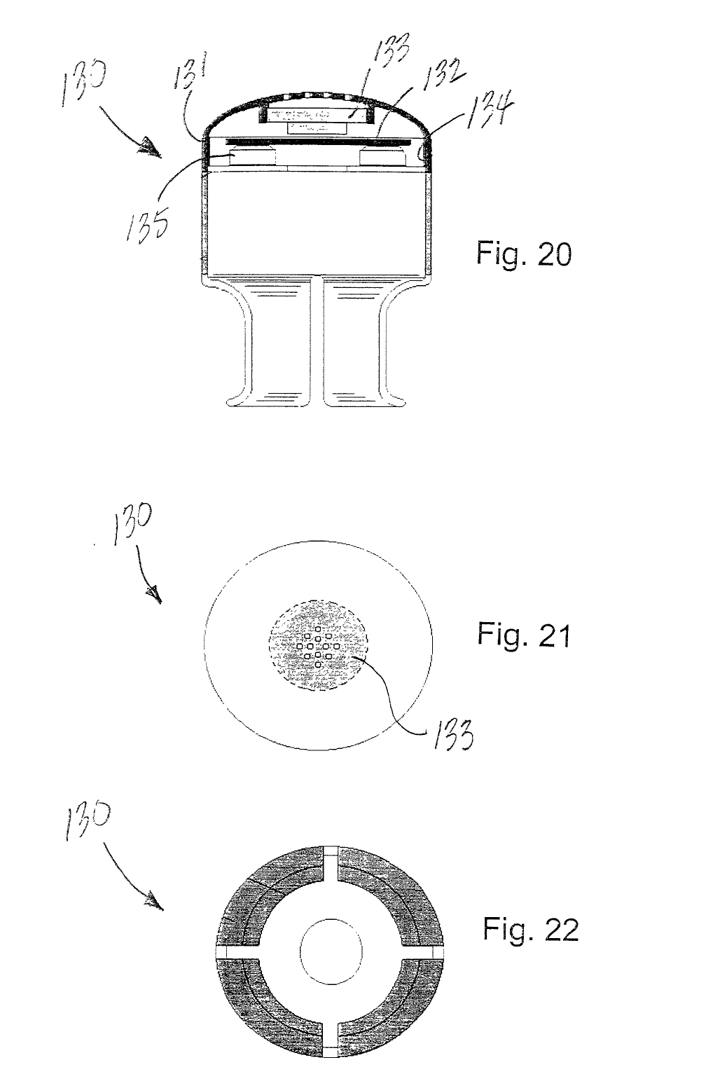

FIGS. 20, 21, and 22 illustrate a sounding door knot cover 130. The door knot cover 130 includes an assembly housing 131 containing a circuit board 132, a loudspeaker 133 electrically connected to the circuit board 132, and a metal sensor 134. The circuit board 132 contains a control circuit and sound output circuit, as previously described. Batteries 135 are carried by the circuit board 132 adjacent the bottom wall of the housing 131 to activate the loudspeaker 133.

When the door knot cover 130 is touched, the metal sensor 134 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 133 which produces an entertaining audible sound or warning.

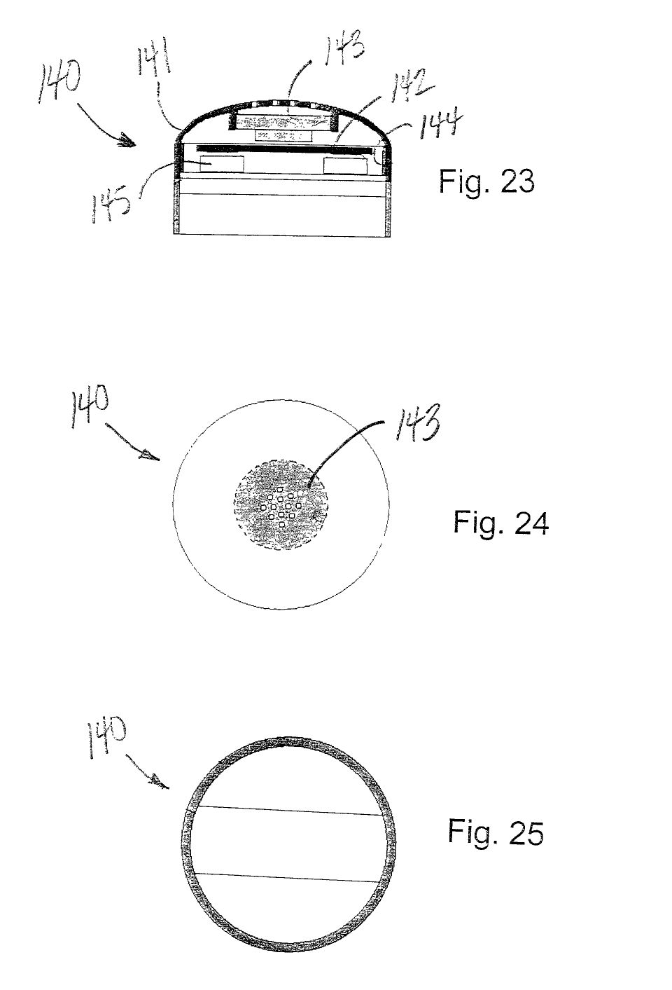

FIGS. 23, 24, and 25 illustrate a sounding stove knot lock 140. The stove knot lock 140 includes an assembly housing 141 containing a circuit board 142, a loudspeaker 143 electrically connected to the circuit board 142, and a metal sensor 144. The circuit board 142 contains a control circuit and sound output circuit, as previously described. Batteries 145 are carried by the circuit board 142 to activate the loudspeaker 143.

When the stove knot lock 140 is touched, the metal sensor 144 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 143 which produces an audible warning.

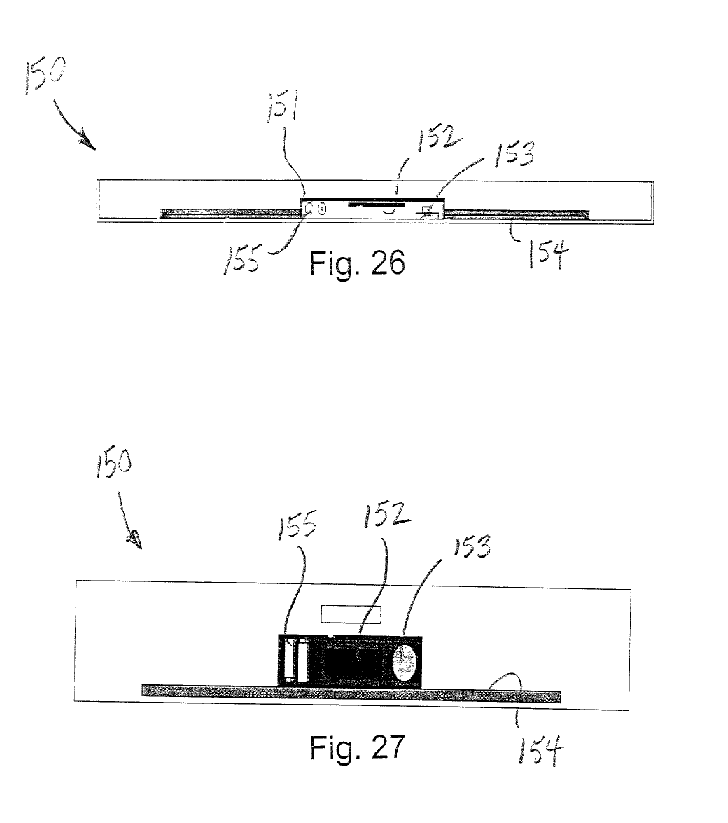

FIGS. 26 and 27 illustrate a sounding stove top shield 150. The stove top shield 150 includes an assembly housing 151 containing a circuit board 152, a loudspeaker 153 electrically connected to the circuit board 152, and a metal sensor 154. The circuit board 152 contains a control circuit and sound output circuit, as previously described. Batteries 155 are operatively connected to the circuit board 152, and serve to activate the loudspeaker 153.

When the stove top shield 150 is touched, the metal sensor 154 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 153 which produces an audible warning.

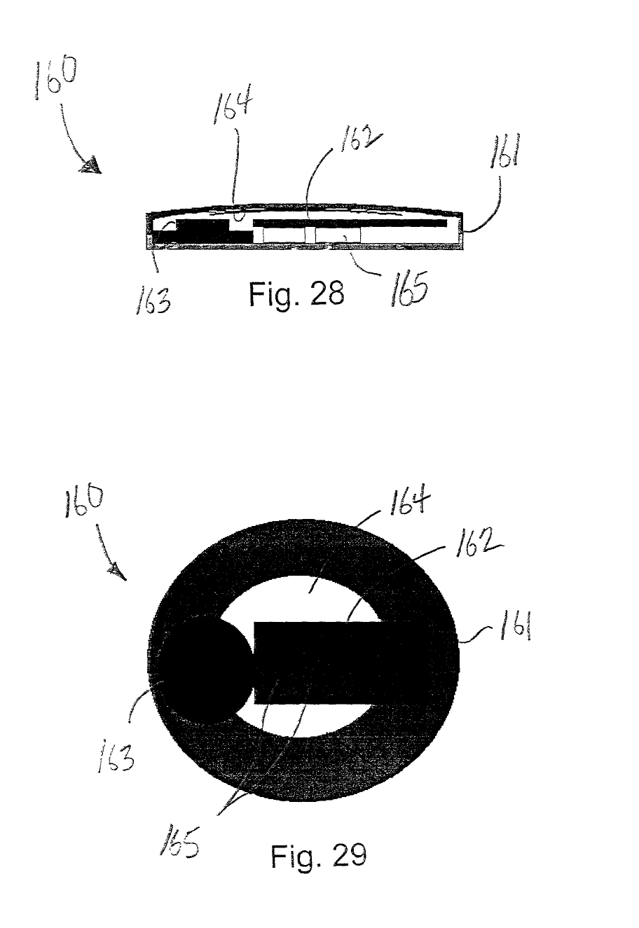

FIGS. 28 and 29 illustrate a sounding badge 160. The sounding badge 160 includes an assembly housing 161 containing a circuit board 162, a loudspeaker 163 electrically connected to the circuit board 162, and a metal sensor 164. The circuit board 162 contains a control circuit and sound output circuit, as previously described. Batteries 165 are operatively connected to the circuit board 162, and serve to activate the loudspeaker 163.

When the sounding badge 160 is touched, the metal sensor 164 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 163 which produces an entertaining audible sound.

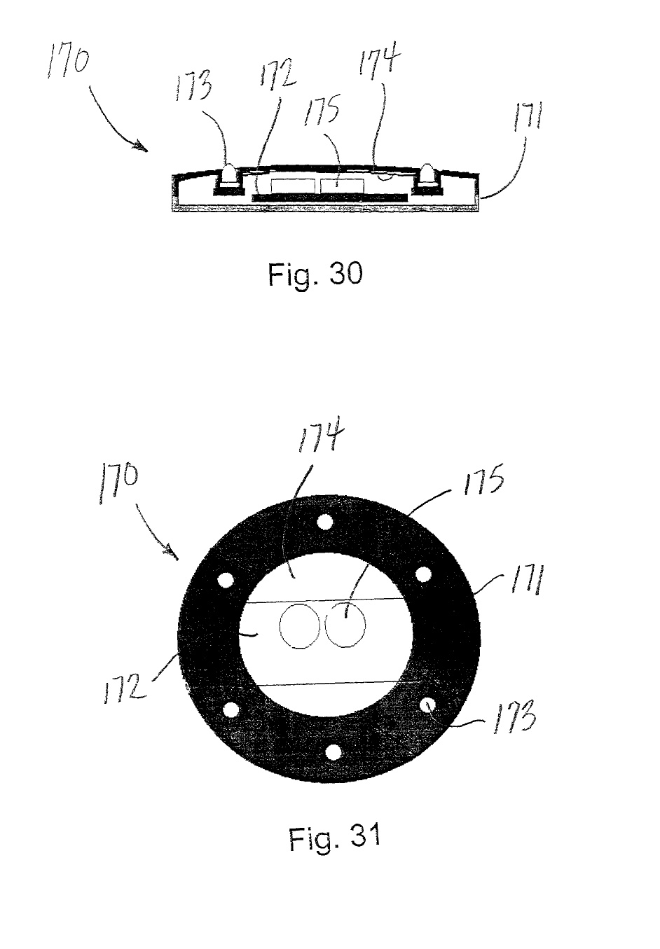

FIGS. 30 and 31 illustrate a light-up badge 170. The light-up badge 170 includes an assembly housing 171 containing a circuit board 172, a number of LED lights 173 electrically connected to the circuit board 172, and a metal sensor 174. The circuit board 172 contains a control circuit and light output circuit, similar to that previously described. Batteries 175 are operatively connected to the circuit board 172, and serve to activate the lights 173.

When the light-up badge 170 is touched, the metal sensor 174 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the light output circuit. The light output circuit cooperates with the battery charge to activate the lights 173.

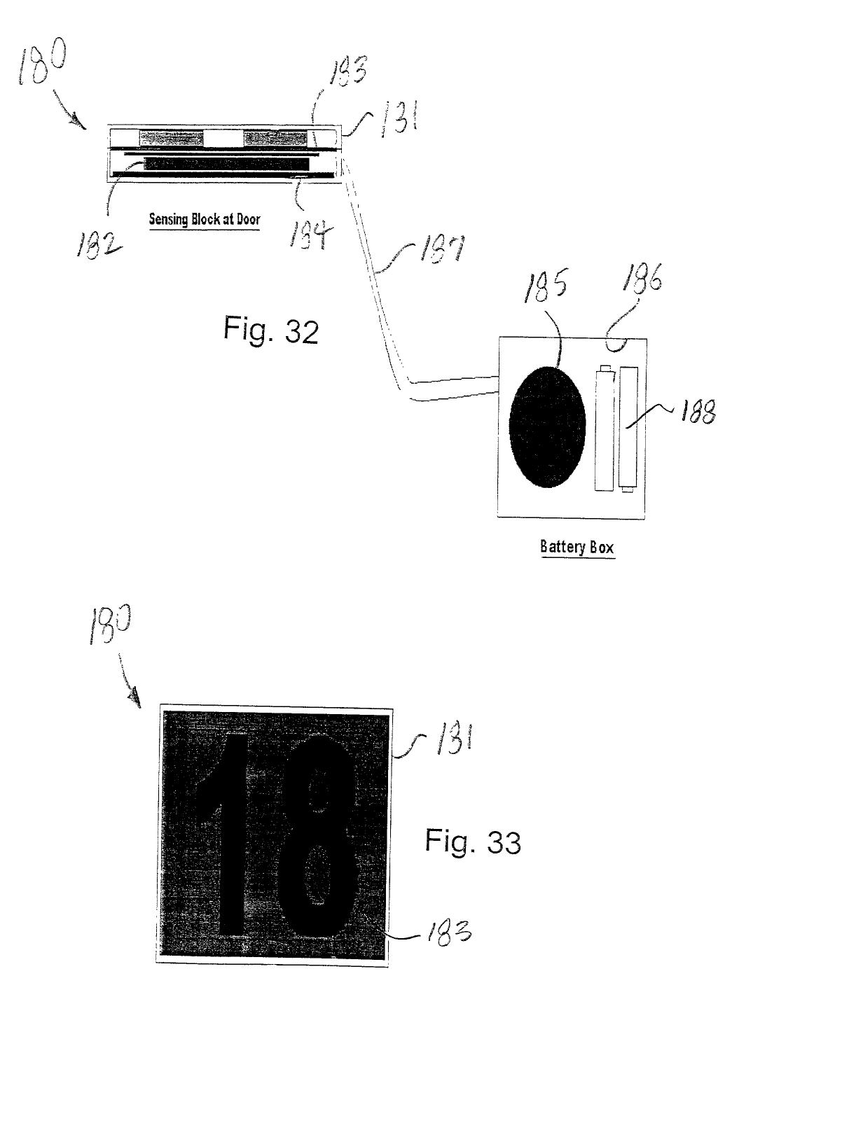

FIGS. 32 and 33 illustrate a safety door chime 180. The door chime 180 includes an assembly housing 181 containing a circuit board 182, metal sensor 183, and radio magnetic frequency shield 184. A loudspeaker 185 is contained in a remote battery box 186 and electrically connected to the circuit board 182 through lead wires 187. The circuit board 182 includes a control circuit and sound output circuit, as previously described. Batteries 188 positioned in the battery box 186 are operatively connected to the circuit board 182, and serve to activate the loudspeaker 185.

When the door chime 180 is touched, the metal sensor 183 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 185 which produces an audible chime from the battery box 186 inside the home.

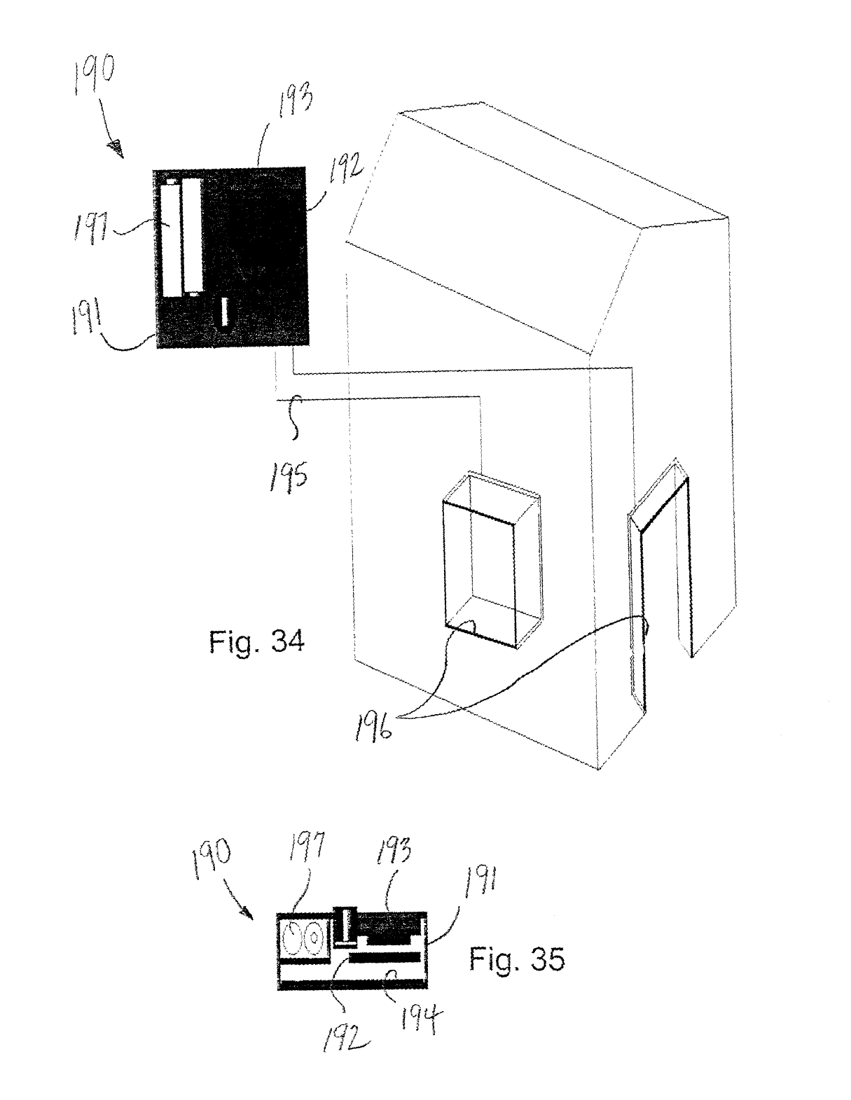

FIGS. 34 and 35 illustrate a home security system 190. The security system 190 includes an assembly housing 191 containing a circuit board 192, a loudspeaker 193 electrically connected to the circuit board 192, and a radio magnetic frequency shield 194. The housing 191 is electrically connected through wires 195 to respective metal sensors 196 strategically positioned adjacent the doors and windows of the home. The circuit board 192 contains a control circuit and sound output circuit, as previously described. Batteries 197 are operatively connected to the circuit board 192 inside the assembly housing 191, and serve to activate the loudspeaker 193.

When a door or window is entered or otherwise touched in an area of the metal sensor 196, the sensor 196 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 193 which produces an audible warning.

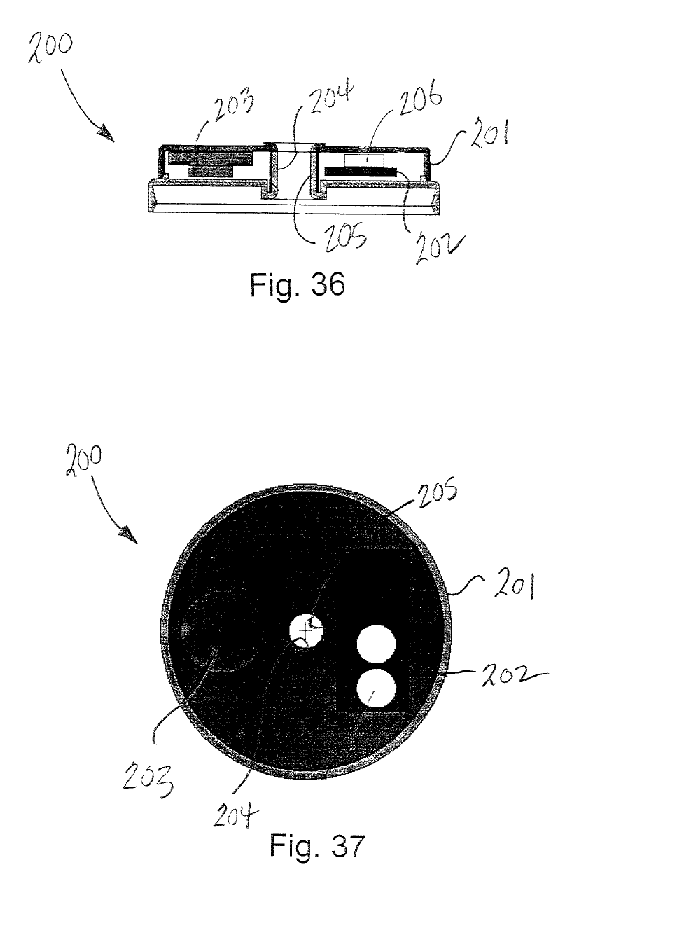

FIGS. 36 and 37 illustrate a sounding cap 200 adapted for use with a cup and drinking straw. The cap 200 includes an assembly housing 201 containing a circuit board 202, a loudspeaker 203 electrically connected to the circuit board 202, and a metal sensor 204 located at a center hole 205 in the housing 201. The center hole 205 receives the drinking straw. The circuit board 202 contains a control circuit and sound output circuit, as previously described. A battery 206 is carried by the circuit board 202 to activate the loudspeaker 203.

Using a user inserts the drinking straw through a center hole 205 formed in the sounding cap 200 and consumes a beverage, the metal sensor 204 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 203 which produces an entertaining, audible sound to the user.

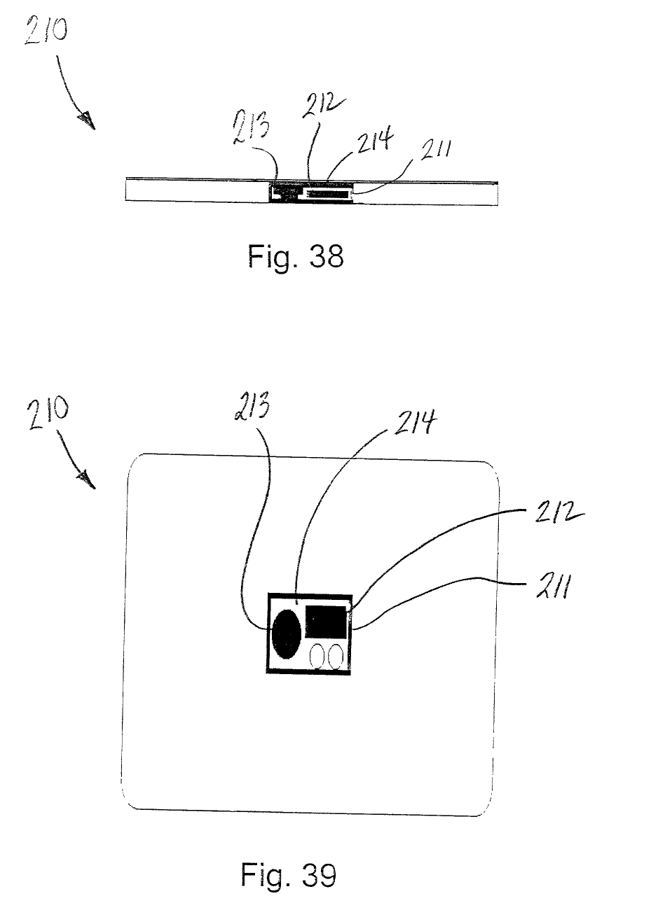

FIGS. 38 and 39 illustrate a sounding table mat 210. The table mat 210 includes an assembly housing 211 containing a circuit board 212, a loudspeaker 213 electrically connected to the circuit board 212, and a metal sensor 214. The circuit board 212 contains a control circuit and sound output circuit, as previously described. Batteries 215 are operatively connected to the circuit board 212, and serve to activate the loudspeaker 213.

When the table mat 210 is touched, the metal sensor 214 detects a capacitance change, as previously described. The new level of capacitance is fed to the control circuit. The capacitance is then amplified and compared to the base level capacitance. If the capacitance change is sufficient to meet or exceed the predetermined threshold, then a signal output is transmitted from the control circuit to the sound output circuit. The sound output circuit cooperates with the battery charge to activate the loudspeaker 213 which produces an entertaining audible sound.

Multiple embodiments a sounding device according to the present invention are described above. Various details of the invention may be changed without departing from its scope. Furthermore, the foregoing description of the preferred embodiment of the invention and the best mode for practicing the invention are provided for the purpose of illustration only and not for the purpose of limitation—the invention being defined by the claims.

We claim:

1. A sounding device, comprising:
(a) an assembly housing;
(b) a sensor comprising a clock signal defining a base level capacitance;
(c) a circuit medium located within said assembly housing and comprising a control circuit and an output circuit, said control circuit being operatively connected to said sensor, and adapted for generating a signal output in response to a threshold change in said base level capacitance; and
(d) a loudspeaker operatively connected to said output circuit, and activated by said signal output for producing outwardly radiating acoustical energy in a frequency range sufficient to be heard by a user.

2. A sounding device according to claim 1, and comprising a battery cooperating with said signal output to operate said loudspeaker.

3. A sounding device according to claim 1, wherein said assembly housing is formed of plastic.

4. A sounding device according to claim 1, and comprising a radio magnetic frequency shield embedded in said assembly housing to protect said sensor from external interference.

5. A sounding device according to claim 1, wherein said device comprises an infant learning cup.

6. A sounding device according to claim 5, and comprising a drinking straw adapted for use in consuming a beverage contained in said learning cup.

7. A sounding device according to claim 6, wherein said learning cup comprising one or more handles.

8. A sounding device according to claim 1, wherein said device comprises a sounding bowl.

9. A sounding device according to claim 1, wherein said device comprises a security gate.

10. A sounding device according to claim 1, wherein said device comprises a door knot cover.

11. A sounding device according to claim 1, wherein said device comprises a stove knot lock.

12. A sounding device according to claim 1, wherein said device comprises a stove top shield.

13. A sounding device according to claim 1, wherein said device comprises a badge.

14. A sounding device according to claim 1, wherein said device comprises a door chime.

15. A sounding device according to claim 1, wherein said device comprises a security system.

16. A sounding device according to claim 1, wherein said device comprises a cap for drinking vessel.

17. A sounding device according to claim 1, wherein said device comprises a table mat.

18. A sounding device, comprising:
(a) an assembly housing;
(b) a sensor comprising a clock signal defining a base level capacitance;
(c) a circuit medium located within said assembly housing and comprising a control circuit and an output circuit, said control circuit being operatively connected to said sensor, and adapted for generating a signal output in response to a threshold change in said base level capacitance; and
(d) a light operatively connected to said output circuit, and activated by said signal output.
